(19) United States
(12) Patent Application Publication
(10) Pub. No.: US 2019/0162892 A1
(43) Pub. Date: May 30, 2019

(54) BACKLIGHT ASSEMBLY, DISPLAY DEVICE INCLUDING THE SAME, AND METHODS OF FABRICATING THE BACKLIGHT ASSEMBLY AND THE DISPLAY DEVICE

(71) Applicant: SAMSUNG DISPLAY CO., LTD., YONGIN-SI (KR)

(72) Inventor: JUNGHOON SHIN, SEONGNAM-SI (KR)

(21) Appl. No.: 16/154,790

(22) Filed: Oct. 9, 2018

(30) Foreign Application Priority Data
Nov. 24, 2017 (KR) 10-2017-0158826

(51) Int. Cl. F21V 8/00; H05K 1/18; G02F 1/1333

(52) U.S. Cl. CPC G02B 6/009; G02B 6/0093; G02B 6/0065; G02B 6/0091; G02F 1/133308; G02B 6/0083; H05K 2201/10106; H05K 2201/10522; G02F 2001/133314; G02F 2001/133317; G02F 2001/13332; G02B 6/0051; G02B 6/0053; G02B 6/0055; H05K 1/181

(57) ABSTRACT

A backlight assembly includes a light guide plate that includes an incidence surface and a light source unit that emits light through a light emitting surface toward the incidence surface. The light source unit includes a light source and a circuit board that are electrically connected to each other. The light source is disposed on the circuit board, and the circuit board is electrically connected to the light source and extends in a first direction. At least a portion of the light guide plate contacts the circuit board at a contact surface that extends along a first direction. A portion of the contact surface is used as a bonding region.

### CROSS-REFERENCE TO RELATED APPLICATIONS

This U.S. non-provisional patent application claims priority under 35 U.S.C. § 119 from, and the benefit of, Korean Patent Application No. 10-2017-0158826, filed on Nov. 24, 2017 in the Korean Intellectual Property Office, the contents of which are herein incorporated by reference in their entirety.

### BACKGROUND

Embodiments of the present disclosure are directed to a backlight assembly, a display device including the same, and methods of fabricating the backlight assembly and the display device.

In general, display devices can be classified as transmissive, transflective, or reflective display devices. Transmissive and transtlective display devices include a display panel that displays images and a backlight assembly that provides light to the display panel.

A backlight assembly includes a light source unit that generates light, and a light guide plate that guides light received from the light source unit toward the display panel. A light guide plate receives light that is incident to an incidence surface and provides the received light to the display panel through an emitting surface.

In conventional technology, a circuit board of the light source unit is bonded to the light guide plate by a tape or adhesive, and a contact surface between the light guide plate and the circuit board can suffer from a non-uniform surface profile. In this case, a fraction of light emitted toward the incidence surface may be totally reflected, thereby causing optical loss. In addition, owing to a weak adhesion at the contact surface, a misalignment issue may occur between the light guide plate and the light source.

### SUMMARY

Some embodiments of the inventive concept can provide a backlight assembly, a display device including the same, and methods of fabricating the backlight assembly and the display device. Here, a backlight assembly includes a light guide plate and a light source unit that are bonded by a laser beam that can prevent total reflection from occurring at a contact surface therebetween and have improved adhesion.

According to some embodiments of the inventive concept, a backlight assembly includes a light guide plate that includes an incidence surface and a light source unit that emits light through a light emitting surface toward the incidence surface. The light source unit includes a light source and a circuit board that are electrically connected to each other. The light source is disposed on the circuit board, and the circuit board extends in a first direction. At least a portion of the light guide plate contacts the circuit board at a contact surface that extends along the first direction. A portion of the contact surface is used as a bonding region.

In some embodiments, the contact surface is a portion of a rear surface of the light guide plate that is perpendicular to the incidence surface, and a width of the contact surface in a second direction that crosses the first direction ranges from about 10 μm to about 100 μm.

In some embodiments, the light guide plate is formed of glass.

In some embodiments, the circuit board includes a base substrate and a circuit layer on the base substrate, and the base substrate is formed of a conductive material.

In some embodiments, the bonding region is formed of a mixed material that includes a material from the circuit board and a material from the light guide plate.

In some embodiments, the light source includes a plurality of light-emitting diodes mounted on the circuit layer and that are arranged in the first direction.

In some embodiments, the bonding region extends in the first direction and has one of a stripe shape that includes one or lines, a zigzag shape, or a dotted-line shape.

In some embodiments, the contact surface is a portion of an incidence surface of the light guide plate.

According to some embodiments of the inventive concept, a display device includes a light guide plate that includes an incidence surface and a light source unit that emits light to the incidence surface. The light source unit includes a light source and a circuit board that are electrically connected to each other. The light source is mounted on the circuit board, and at least a portion of the light guide plate is in contact with the circuit board. A bonding region is formed where the portion of the light guide plate contacts the circuit board. The bonding region is formed of a mixed material that includes a material from the circuit board and a material from the light guide plate.

In some embodiments, the light guide plate is formed of glass.

in some embodiments, the circuit board includes a base substrate and a circuit layer disposed on the base substrate. The base substrate is formed of a conductive material.

In some embodiments, the bonding region is a portion of a rear surface of the light guide plate that is perpendicular to the incidence surface.

In some embodiments, the bonding region is a portion of the incidence surface.

In some embodiments, the backlight assembly includes a display panel disposed on the backlight assembly that receives light from the backlight assembly. The display panel includes a first substrate, a second substrate that faces the first substrate, and a liquid crystal layer interposed between the first and second substrates.

In some embodiments, the backlight assembly further includes at least one optical sheet disposed on the light guide plate, and a reflection sheet disposed below the light guide plate.

According to some embodiments of the inventive concept, a method of fabricating a backlight assembly includes providing a circuit board, providing a light source unit on the circuit board, providing a light guide plate on the circuit board adjacent to the light source unit, and forming a bonding region between the light guide plate and the circuit board using a laser beam.

In some embodiments, forming a bonding region includes irradiating the laser beam vertically through the light guide plate and into at least a portion of the circuit board. The bonding region is formed along an imaginary line where the circuit board and the light guide plate are in direct contact with each other.

In some embodiments, providing the circuit board includes sequentially depositing an insulating layer and a circuit layer on a conductive substrate. The insulating layer and the circuit layer expose a portion of the conductive substrate, and the insulating layer electrically separates the conductive substrate from the circuit layer.

In some embodiments, the laser beam is a femto-second laser beam.

In some embodiments, the bonding region is formed by melting at least a portion of the light guide plate and at least a portion of the circuit substrate using the laser beam.

### BRIEF DESCRIPTION OF THE DRAWINGS

FIG. 1 is an exploded perspective view of a display device according to some embodiments of the inventive concept.

FIG. 2 is a cross-sectional view of a display device according to some embodiments of the inventive concept.

FIG. 3 is a side view of a portion of a backlight assembly according to some embodiments of the inventive concept.

FIG. 4A is a side view of a backlight assembly according to some embodiments of the inventive concept.

FIG. 4B is a plan view of a backlight assembly according to some embodiments of the inventive concept.

FIG. 5A is a side view of a backlight assembly according to some embodiments of the inventive concept.

FIG. 5B is a rear view of a backlight assembly according to some embodiments of the inventive concept.

FIGS. 6A to 6C illustrate shapes of bonding regions according to some embodiments of the inventive concept.

FIG. 7 is a flow chart of a method of fabricating a backlight assembly according to some embodiments of the inventive concept.

FIGS. 8A to 8F illustrate a method of fabricating a backlight assembly according to some embodiments of the inventive concept.

It should be noted that the use of similar or identical reference numbers in the various drawings is intended to indicate the presence of a similar or identical element or feature.

### DETAILED DESCRIPTION

Exemplary embodiments of the inventive concept will now be described more fully with reference to the accompanying drawings, in which exemplary embodiments are shown. Exemplary embodiments of the inventive concept may, however, be embodied in many different forms and should not be construed as being limited to the embodiments set forth herein. In the drawings, the thicknesses of layers and regions may be exaggerated for clarity. Like reference numerals in the drawings may denote like elements, and thus their description may be omitted.

It will be understood that when an element is referred to as being “connected” or “coupled” to another element, it can be directly connected or coupled to the other element or intervening elements may be present.

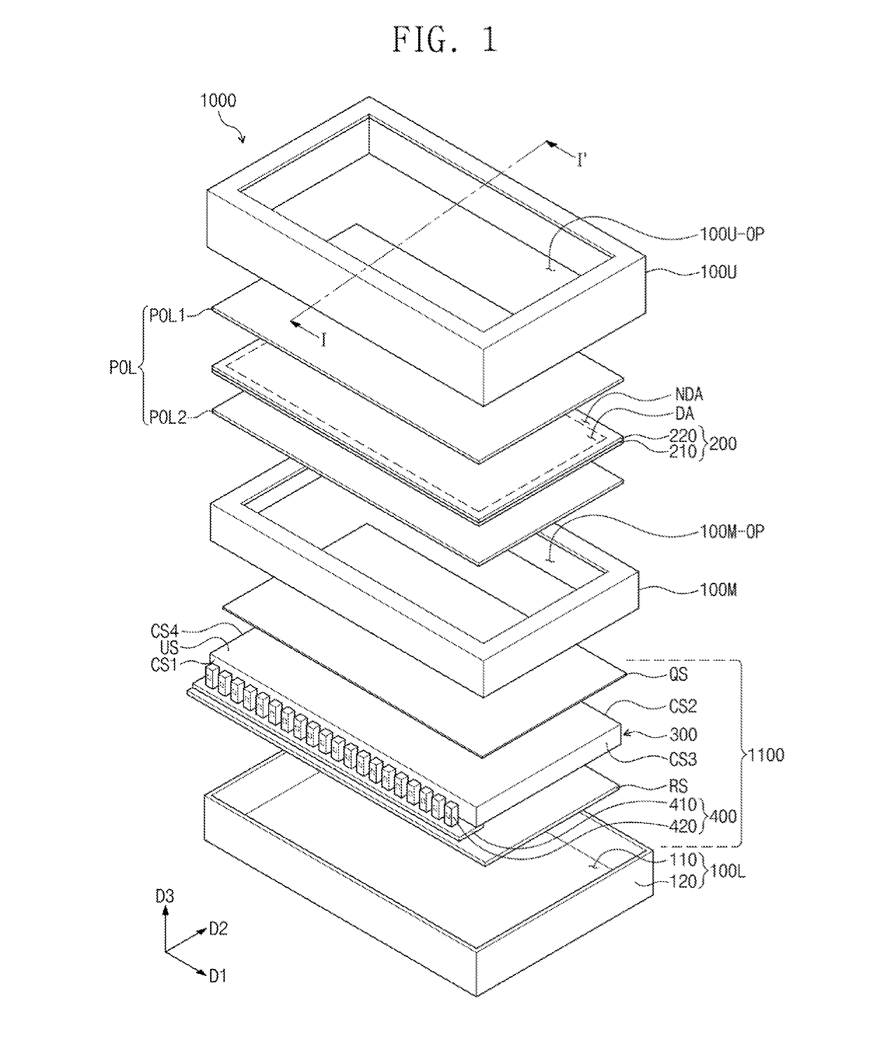

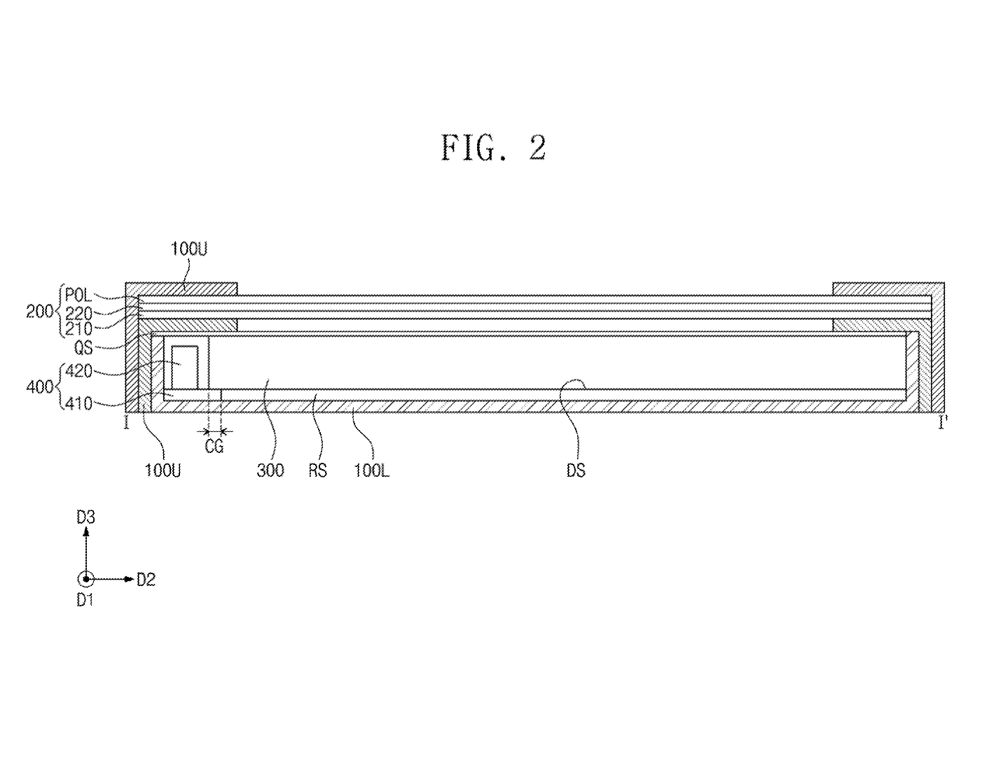

FIG. 1 is an exploded perspective view of a display device according to some embodiments of the inventive concept. FIG. 2 is a cross-sectional view of a display device according to some embodiments of the inventive concept. Hereinafter, a display device will be described in detail with reference to FIGS. 1 and 2.

As shown in FIG. 1, according to some embodiments, a display device 1000 include protecting parts 100U, 100M, and 100L, a display panel 200, and a backlight assembly 1100.

According to some embodiments, protecting parts 100U, 100M, and 100L include an upper protecting part 100U, a lower protecting part 100L, and an intermediate protecting part 100M between the upper protecting part 100U and the lower protecting part 100L. The upper protecting part 100U and the lower protecting part 100L are combined with each other to contain and protect other elements of the display device 1000.

According to some embodiments, the upper protecting part 100U is provided on the display panel 200. The upper protecting part 100U includes an opening 100U-OP. The opening 100U-OP exposes a region of the display panel 200, such as a display region DA that is used to display an image.

According to some embodiments, the upper protecting part 100U overlaps with other region of the display panel 200, such as a non-display region NDA. The non-display region NDA is provided around or near the display panel 200 and does not display an image.

According to some embodiments, the lower protecting part 100L contains the backlight assembly 1100 therein. The lower protecting part 100L includes a bottom portion 110 and a sidewall portion 120 that upwardly extend from the bottom portion 110. The bottom portion 110 may have a rectangular or quadrilateral shape, when viewed in a plan view. The sidewall portion 120 extends upward from four sides of the bottom portion 110.

According to some embodiments, the intermediate protecting part 100M is disposed between the upper protecting part 100U and the lower protecting part 100L. The intermediate protecting part 100M has a rectangular frame that overlaps the non-display region NDA of the display panel 200. The intermediate protecting part 100M includes an opening 100M-OP. The intermediate protecting part 100M supports the display panel 200.

According to some embodiments, the display panel 200 receives light from the backlight assembly 1100 and generates an image. The display panel 200 may be a transmissive or transflective display panel. For example, the display panel 200 may be a liquid crystal display panel, an electrophoresis display panel, or an electrowetting display panel.

In a present embodiment, the display panel 200 is a liquid crystal display panel that includes a first substrate 210, a second substrate 220, and a liquid crystal layer disposed between the first substrate 210 and the second substrate 220.

According to some embodiments, the display panel 200 includes a flexible circuit film disposed along a first direction D1 that is electrically connected to other electrical elements in the display panel 200. A driving chip is mounted on the flexible circuit film as a chip-on-film (CGF). The driving chip includes a data or gate driving part that control operations of the display panel 200. In addition, the display panel 200 includes a printed circuit board electrically connected to the flexible circuit film. A control unit is mounted on the printed circuit board. In some embodiments, the control unit may be configured to output signals that are used to start operations of the data or gate driving part, in response to various received input signals. In certain embodiments, a plurality of flexible circuit films are arranged in the first direction D1.

In a present embodiment, the display panel 200 includes polarizing plates POL. The polarizing plates POL change a polarization state of light received from the backlight assembly 1100. For example, a first polarizing plate POL1 is disposed on the display panel 200. A second polarizing plate POL2 is disposed between the display panel 200 and the intermediate protecting part 100M. Each of the polarizing plates POL is a film. However, embodiments of the inventive concept are not limited to the above example, and for example, the polarizing plate may be disposed in the display panel.

According to some embodiments, the backlight assembly 1100 includes a light guide plate 300 and a light source unit 400. The backlight assembly 1100 is disposed or stored in the lower protecting part 100L. The backlight assembly 1100 is disposed below the display panel 200 and emits light toward the display panel 200.

According to some embodiments, the light guide plate 300 is disposed below the display panel 200. The light guide plate 300 guides light received from the light source unit 400 to be propagated toward the display panel 200.

According to some embodiments, the light guide plate 300 includes a first surface US, a second surface DS the faces the first surface US, and a plurality of connecting surfaces that connect the first surface US to the second surface DS. The light guide plate 300 includes at least one incidence surface. The light guide plate 300 has a rectangular plate shape.

According to some embodiments, the plurality of connecting surfaces include first and second side surfaces CS1 and CS2, which are opposite to each other in the first direction D1, and third and fourth side surfaces CS3 and CS4, which are opposite to each other in a second direction D2 that crosses the first direction D1.

In some embodiments, at least one of the connection surfaces is used as an incidence surface. The incidence surface is a surface into which light emitted from the light source unit is incident. FIG. 1 illustrates an example in which the first side surface CS1 parallel to the first direction D1 is the incidence surface. The light guide plate 300 guides light incident into the first side surface CS1 to he emitted toward the display panel 200 through the first surface US. However, embodiments of the inventive concept are not limited to the above example, and in other embodiments, one of the second to fourth side surfaces CS2, CS3, or CS4, or two or more of the first to fourth side surfaces CS2, CS3, or CS4 may be used as the incidence surface. The light guide plate 300 is formed of or includes a material having high optical transmittance of visible light. In some embodiments, the light guide plate 300 is formed of an optically transparent material. For example, the light guide plate 300 may include a glass substrate, a plastic substrate, or a combination thereof. For the sake of simplicity, the description that follows will refer to an embodiment in which the light guide plate 300 is formed of glass. The light source unit 400 includes a circuit board 410 and a light source 420. The circuit board 410 is electrically connected to the light source 420 and controls the emission of light from the light source 420. As shown in FIG. 1, a plurality of the light sources 420 are disposed on the circuit board 410. In addition, the circuit board 410 includes a plurality of circuit boards that respectively correspond to the plurality of light sources.

According to some embodiments, an optical sheet QS is disposed on the light guide plate 300. The optical sheet QS diffuses and condenses light received from the light guide plate 300. The optical sheet QS includes a diffusion sheet, a prism sheet, and a protection sheet. Of the sheets constituting the optical sheet QS, the diffusion sheet is closest to the light guide plate 300 and disperses light received from the light guide plate 300 to prevent the light from being locally condensed. The prism sheet includes a plurality of triangular pillar shaped prisms on a surface of the diffusion sheet to condense light that has been diffused by the diffusion sheet in a direction perpendicular to the display panel 200. The protection sheet is disposed on the prism sheet to protect a surface of the prism sheet. Furthermore, the protection sheet diffuses light to increase uniformity of the light distribution.

According to some embodiments, a reflection sheet RS is disposed below the light guide plate 300. The reflection sheet RS reflects light that has propagated downward from the light guide plate 300 back toward the light guide plate 300. The reflection sheet RS upwardly reflects light that has propagated downward from the light guide plate 300. The reflection sheet RS is formed of or includes an optically reflective material. For example, the reflection sheet RS may be formed of or include aluminum (Al) or silver (Ag).

In a present embodiment, the light guide plate 300 is attached to the circuit board 410 and in contact with at least a portion of the circuit board 410. Accordingly, there is a contact surface CG between the light guide plate 300 and the circuit substrate. The contact surface CG is where the light guide plate 300 and the circuit hoard 410 make contact with each other.

In a present embodiment, the light guide plate 300 overlaps the circuit board 410 in a plan view. Accordingly, a portion of the second surface DS of the light guide plate 300 that overlaps the circuit board 410 and extends in an extension direction, such as the first direction D1, of the circuit board 410 forms the contact surface CG.

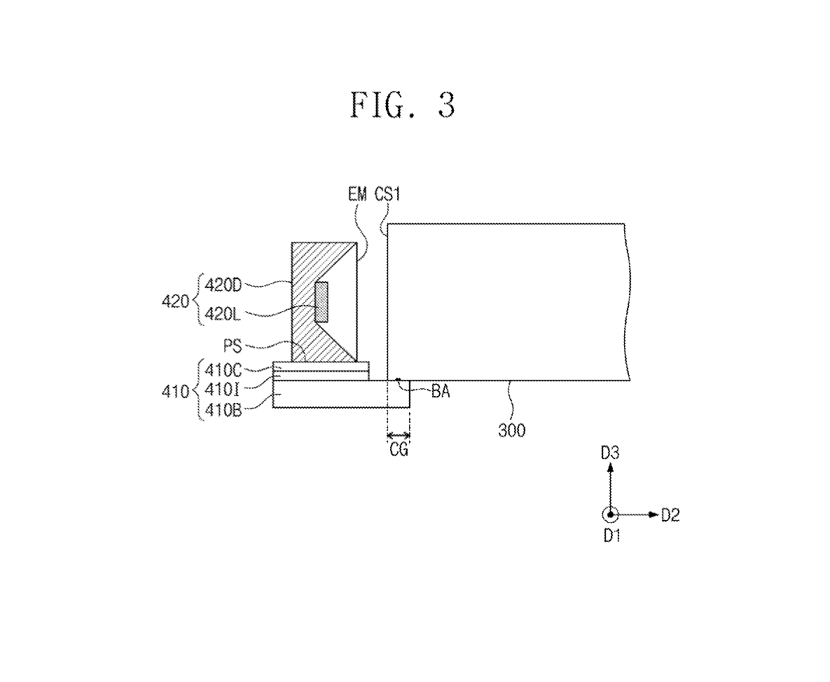

FIG. 3 is a side view of a portion of a backlight assembly according to some embodiments of the inventive concept.

As shown in FIG. 3, according to some embodiments, when viewed in a sectional view, the circuit board 410 includes a conductive substrate 410B, an insulating layer 410I, and a circuit layer 410C that are sequentially stacked in a thickness direction of the circuit board 410.

According to some embodiments, the conductive substrate 410B radiates heat generated by the light source 420 to the outside. Accordingly, the conductive substrate 410B is formed of or includes at least one material having high thermal conductivity. For example, the conductive substrate 410B may be formed of or include at least one of a metal or a metal oxide. For example, the conductive substrate 410B may be formed of or include aluminum (Al) or aluminum oxide (Al₂O₃).

According to some embodiments, the insulating layer 410I is disposed on the conductive substrate 410B, when viewed in a sectional view. The insulating layer 410I electrically separates the conductive substrate 410B from the circuit layer 4100. The insulating layer 410I also conducts heat generated by the light source 420 to the conductive substrate 410I. The insulating layer 410I is formed of or includes an electrically insulating and thermally conductive material. For example, the insulating layer 410I may include a thermally conductive polymer material, a thermally conductive silicone, a carbon-containing prepreg, or a carbon fiber. However, embodiments of the inventive concept are not limited to the above example, and in other embodiments, any material that is an effective electrical insulator and an effective thermal conductor can be used as the insulating layer 410I.

According to some embodiments, the circuit layer 410C is electrically connected to the light source 420. For example, the circuit layer 410C is connected to electrodes of the light source 420. The circuit layer 410C may include conductive lines or conductive pads that are respectively connected to the electrodes. The circuit layer 410C is formed of or includes a metal, such as copper.

According to some embodiments, the light source 420 includes a light emitting diode (LED) 420L and a body portion 420D. The light source 420 is disposed on the circuit layer 410C, when viewed in a sectional view, and is electrically connected to the circuit layer 410C. The light emitting diode 420L generates light in response to an electrical signal received from the circuit layer 410C. The light source 420 is mounted on a mounting surface PS, which is the top surface of the circuit board 410.

According to some embodiments, the light emitting diode 420L includes a first electrode, an n-type semiconductor layer, an active layer, a p-type semiconductor layer, and a second electrode that are sequentially stacked. Here, the first electrode is electrically connected to the circuit layer 410C and the second electrode faces the first electrode and is electrically connected to the circuit layer 410C. When a driving voltage is applied to the light emitting diode 420L, light generated by the recombination of electrons and holes is emitted from the light emitting diode 420L.

According to some embodiments, the body portion 420D has a concave shape with one open side. For example, the body portion 420D includes a planar portion and a partition wall portion bent from the planar portion to enclose the planar portion. The body portion 420D defines an exterior shape of the light source 420. The planar portion fastens the light emitting diode 420L.

In a present embodiment, the light source 420 includes one light emitting diode 420L. However, embodiments of the inventive concept are not limited to the above example, and in other embodiments, the light source 420 includes a plurality of light emitting diodes, which can display the same color or different colors.

According to some embodiments, the light source 420 has at least one light emitting surface EM. The light source 420 emits light through the light emitting surface EM. The light emitting surface EM faces the incidence surface CS1 of the light guide plate 300.

In a present embodiment, the light emitting surface EM is perpendicular to the mounting surface PS. For example, the light source 420 is a side emission type light source.

According to some embodiments, at least a portion of the light guide plate 300 in contact with the circuit board 41 that extends in the first direction D1 forms the contact surface CG. The contact surface CG has a width in the second D2 direction that ranges from about 10 μm to about 100 μm. When the width of the contact surface CG is less than 10 μm, a contact area may be too small to stably maintain the coupling between the light source unit 400 and the light guide plate 300. In this case, there may be a misalignment between the light source unit 400 and the light guide plate 300, and thus, light may not be properly emitted to the display panel 200. When the width of the contact surface CG is greater than 100 μm, the contact area is increased, which may lead to a total reflection of light emitted from the light source 420 and a consequent optical loss.

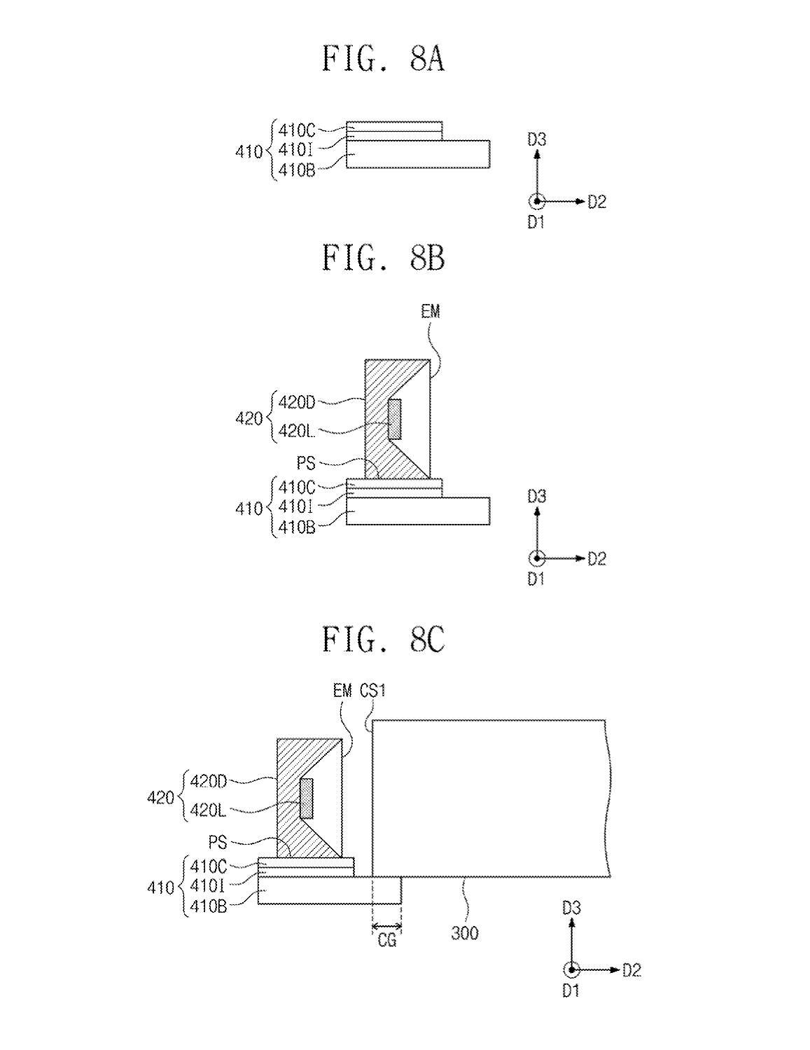

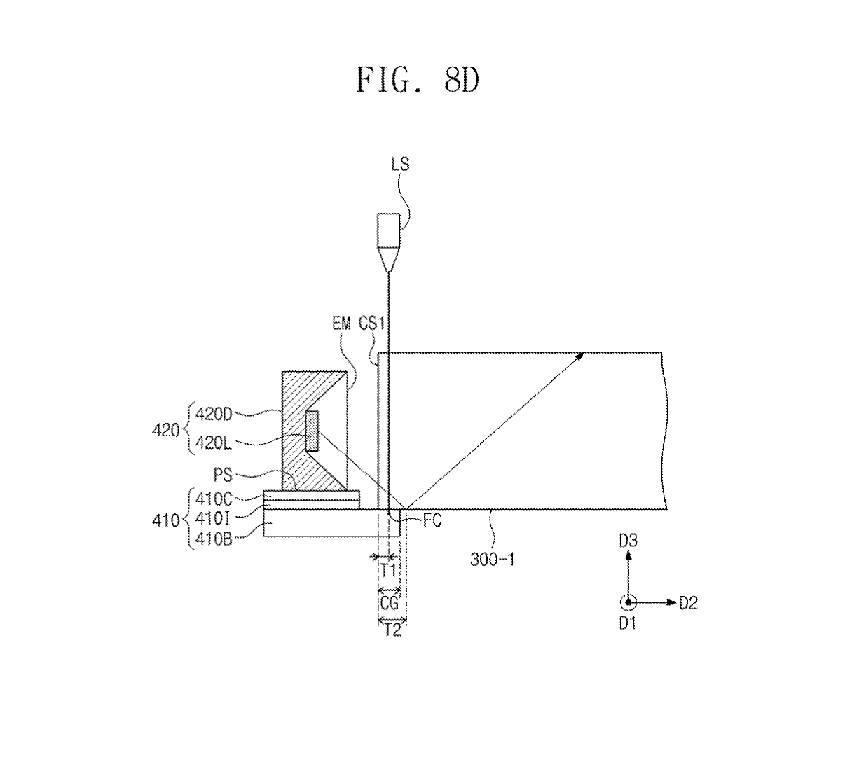

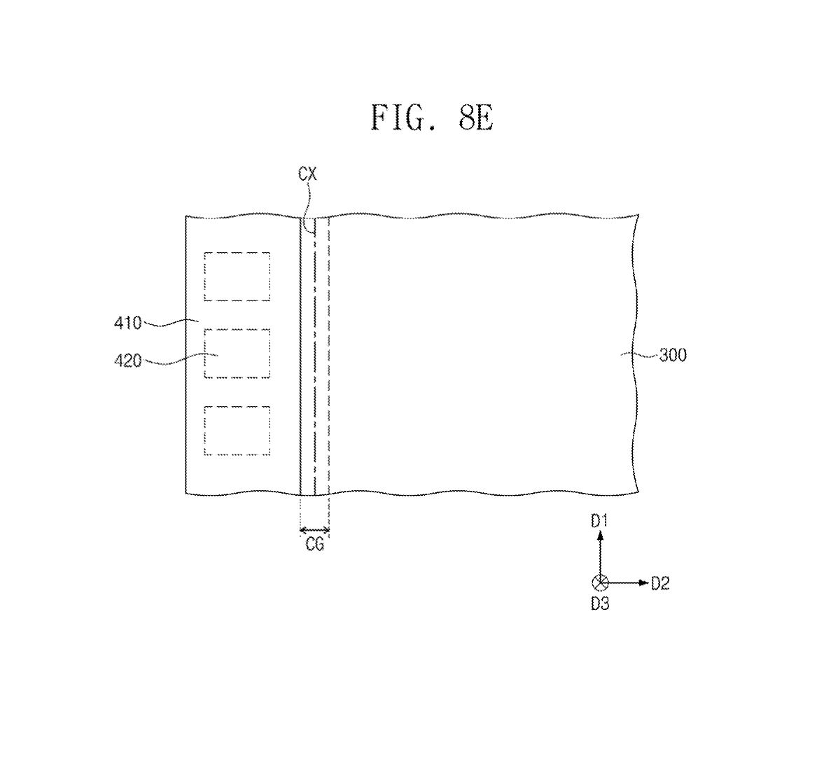

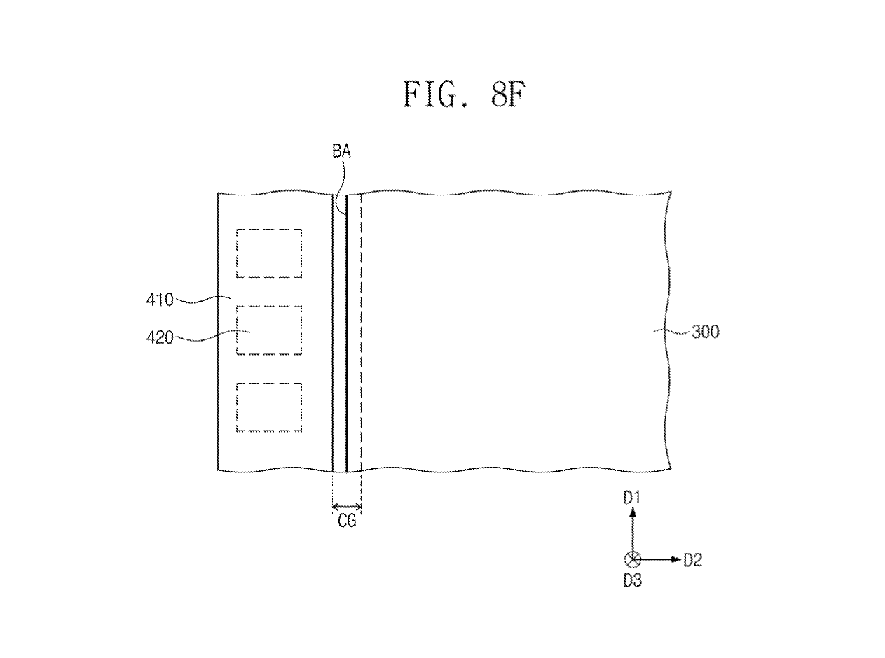

In some embodiments, the display device 1000 includes a bonding region BA on the contact surface CG. The bonding region BA is characterized by a mixed material, in which a glass, such as the light guide plate 300, and a metal, such as the circuit board 410 are mixed. When, in a backlight assembly fabrication process to be described below, a laser beam LS (e.g., see FIG. 8D) is irradiated to bond the light guide plate 300 and the light source unit 400 to each other, irradiated portions of the light guide plate 300 and the light source unit 400 are melted and solidified, and the bonding region BA results from the solidification of the light guide plate 300 and the light source unit 400. That is, since the bonding region BA is formed as a result of the melting and mixing of glass from the light guide plate 300 and metal from the circuit board 410, the bonding region BA is formed of a different material from the light guide plate 300 and the circuit board 410. Thus, the bonding region BA has a relatively non-uniform surface profile, compared with other regions of the contact surface CG.

According to some embodiments, since the bonding region BA is formed from the melting and solidification of at least portions of the light guide plate 300 and the light source unit 400 caused by the irradiation of the laser beam LS, the bonding region BA protrudes from the contact surface CG in a third direction D3, which is a thickness direction of the light guide plate 300.

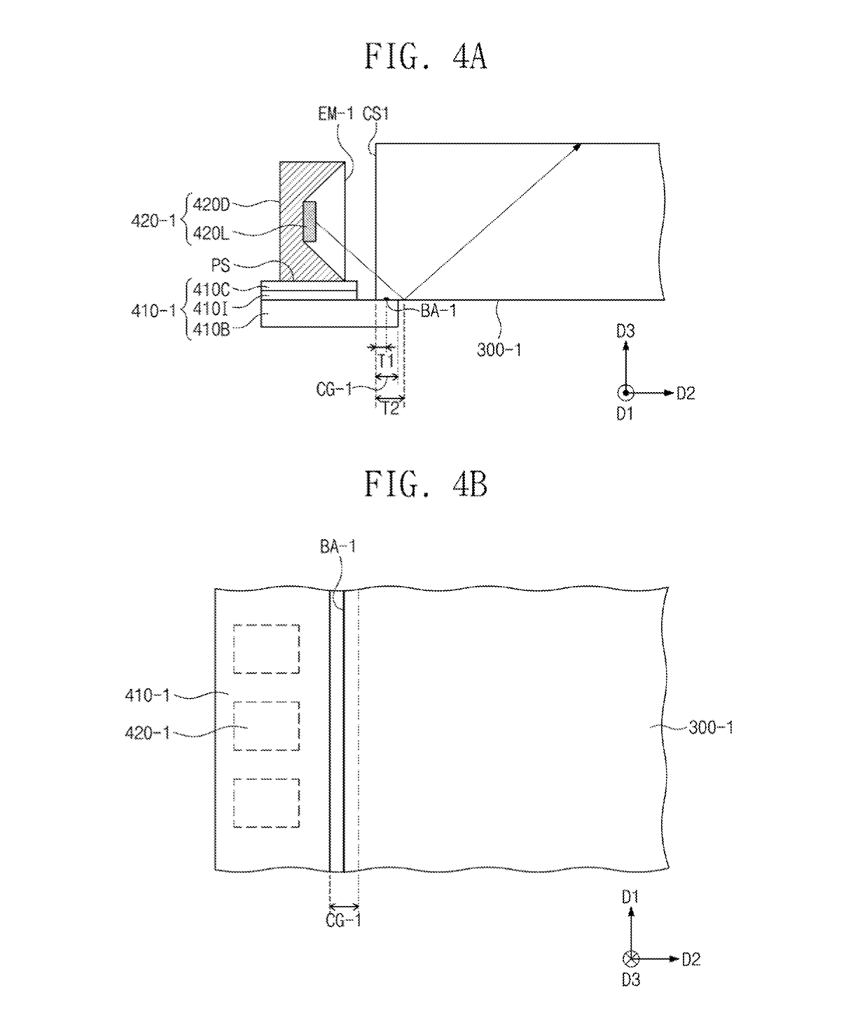

FIG. 4A is a side view of a backlight assembly according to some embodiments of the inventive concept. FIG. 4B is a plan view of a backlight assembly according to some embodiments of the inventive concept. For convenience of illustration, only some elements of the backlight assembly 1100 are illustrated in FIGS. 4A and 4B.

As shown in FIG. 4A, according to some embodiments, a light guide plate 300-1 has a rear surface perpendicular to an incidence surface CS1, and at least a portion of the rear surface of the light guide plate 300-1 adjacent to the incidence surface CS1 is in contact with a circuit board 410-1, thereby serving as a contact surface CG-1. A bonding region BA-1 is formed on the contact surface CG-1.

According to some embodiments, a first distance T1 from the incidence surface CS1 to the bonding region BA-1 is less than a second distance T2 from the incidence surface CS1 to an incidence position of the rear surface of the light guide plate 300-1, which is located on a propagation path of an edge light emitted from a light source 420-1. Here, edge light refers to a fraction of light that is incident into the light guide plate 300-1 at the largest incident angle relative to the rear surface of the light guide plate 300-1. In FIG. 4A, the arrow depicts a fraction of light that is incident into the light guide plate 300 through the light emitting surface EM-1.

FIG. 4B shows the back surface of the light guide plate 300-1 and the conductive substrate 410B, where the illuminated light source 420-1 is shown by a dashed line. As shown in FIG. 4B, according to some embodiments, a plurality of light sources 420-1 are disposed on the circuit board 410-1. The bonding region BA-1 extends in the first direction D1, which is an arrangement direction of the light sources 420-1. In a present embodiment, the bonding region BA-1 has a linear shape that extends in the first direction D1. The bonding region BA-1 is formed on the contact surface CG-1.

In a present embodiment, since the first distance T1 is less than the second distance T2, it may be possible to prevent incident light emitted from the light source 420-1 from being reflected by the bonding region BA-1, as described above. Thus, it may be possible to prevent the total reflection and the consequent optical loss that may occur in a conventional backlight assembly, such as when a tape or adhesive is formed on the bonding region to provide a non-flat surface. Furthermore, the bonding region BA-1 is formed of a mixed material that is formed by the melting and solidification of glass from the light guide plate 300-1 and metal from the circuit board 410-1 caused by the irradiation of the laser beam LS, and thus, the display device 1000 has improved bonding or adhesion, compared with a conventional backlight assembly, in which the tape or adhesive is used. For example, the bonding strength between the light guide plate 300-1 and the circuit board 410-1 is increased, and thus it is possible to more precisely and more stably align the light guide plate 300-1 to the circuit board 410-1.

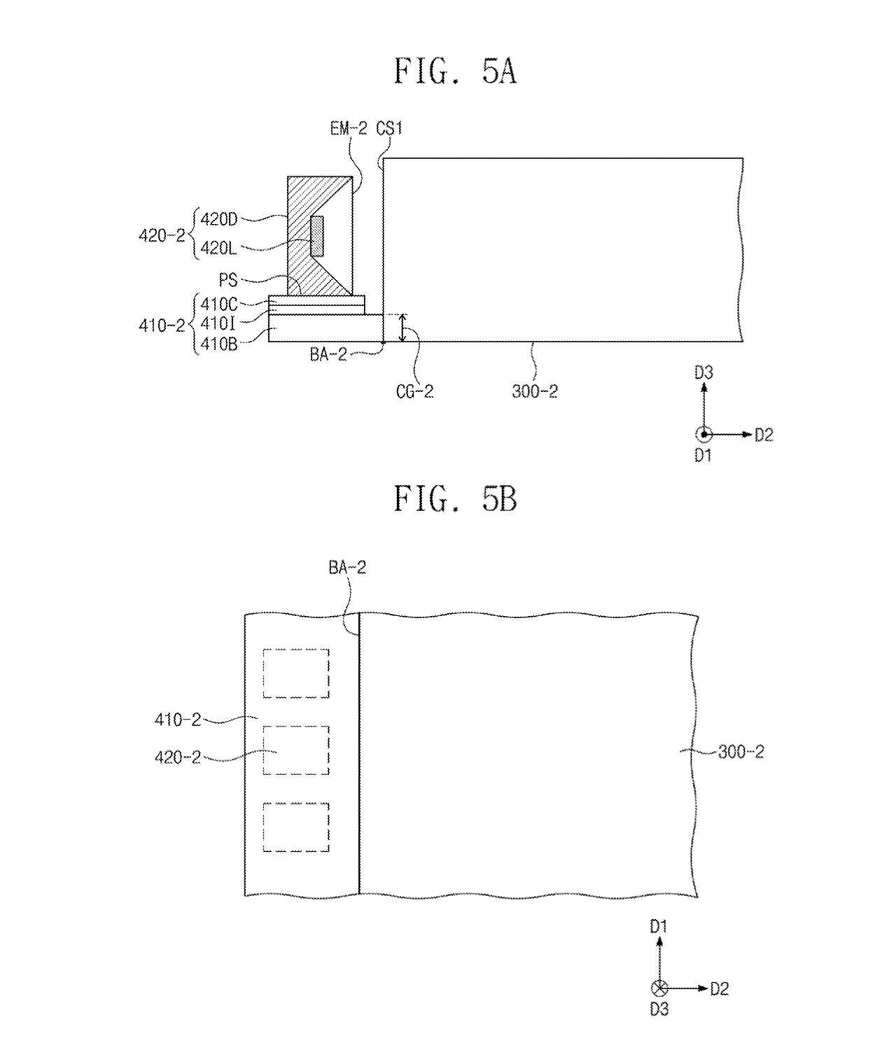

FIG. 5A is a side view of a backlight assembly according to some embodiments of the inventive concept. FIG. 5B is a rear view of a backlight assembly according to some embodiments of the inventive concept. For concise description, an element previously described with reference to FIGS. 4A and 4B may be identified by a similar or identical reference number without repeating a description thereof.

As shown in FIG. 5A, according to some embodiments, a contact surface CG-2 is defined on an incidence surface CS1 of a light guide plate 300-2. In a present embodiment, a light guide plate 300-2 and a circuit board 410-2 do not overlap each other in a top plan view, but they overlap each other in a side view. The incidence surface CS1 of the light guide plate 300-2 is in contact with a side surface of the circuit board 410-2. Thus, a portion of the incidence surface CS1 forms the contact surface CG-2 where the circuit board 410-2 and the light guide plate 300-2 are in direct contact with each other.

According to some embodiments, when the width of the contact surface CG-2 in the third D3 direction is less than 10 μm, a contact area may be too small to stably maintain the bonding strength between the light guide plate 300-2 and the circuit board 410-2. By contrast, when the width of the contact surface CG-2 is greater than 100 μm, incident light from a light source 420-2 may be partly reflected by the contact surface CG-2, which may lead to an optical loss through the incidence surface CS1 of the light guide plate 300-2. Thus, the contact surface CG-2 has a width ranging from about 10 μm to about 100 μm, but embodiments of the inventive concept is not limited thereto.

FIG. 5B shows the back surface of the light guide plate 300-2 and the conductive substrate 410B, where the illuminated light source 420-2 is shown by a dashed line. As shown in FIG. 5B, according to some embodiments, a bonding region BA-2 is formed at an end portion of the contact surface CG-2 where the light guide plate 300-2 and the circuit board 410-2 are in contact with each other, and is exposed to the outside. The bonding region BA-2 protrudes from the contact surface CG-2 in a negative D3 direction opposite to the thickness or third direction D3 of the light guide plate 300-2.

Thus, according to some embodiments, the bonding region BA-2 formed on the rear surface of the light guide plate 300-2 can be recognized by a user. Since the bonding region BA-2 is exposed to the outside, the bonding region BA-2 is not located on a propagation path light emitted from the light source unit 400-2. Thus, total reflection and the consequent optical loss can be prevented.

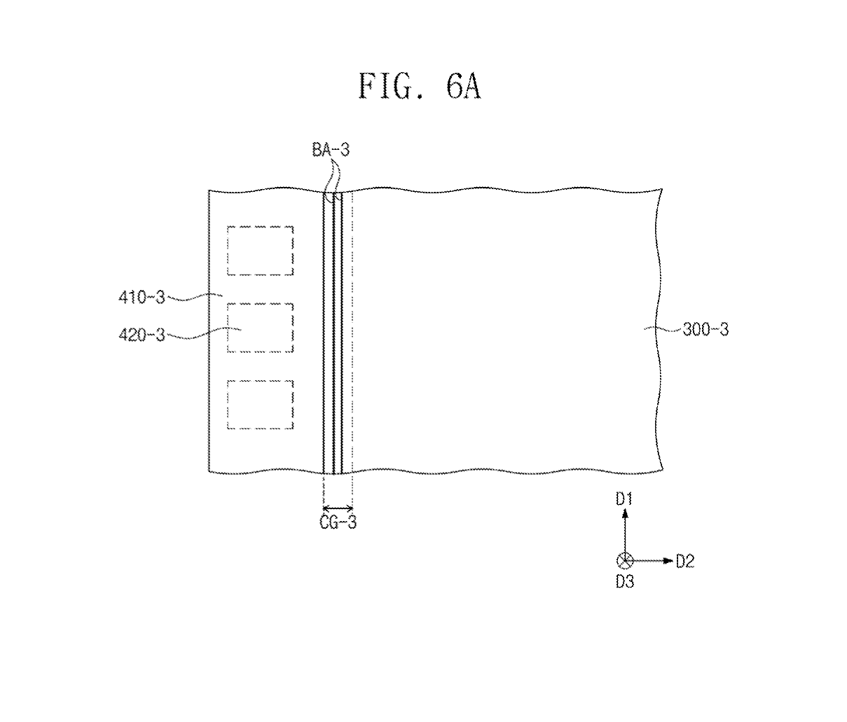

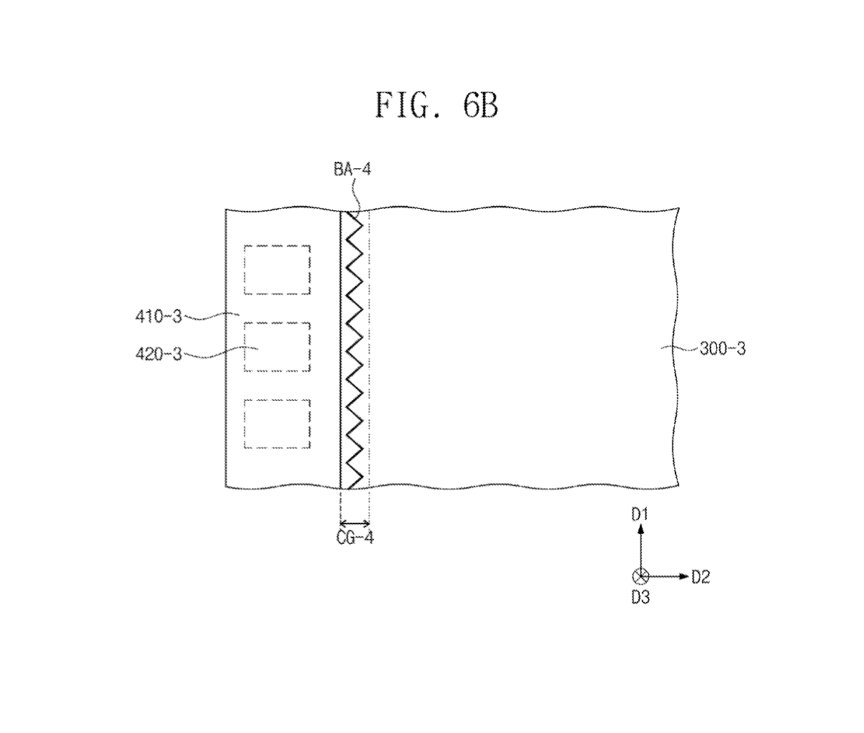

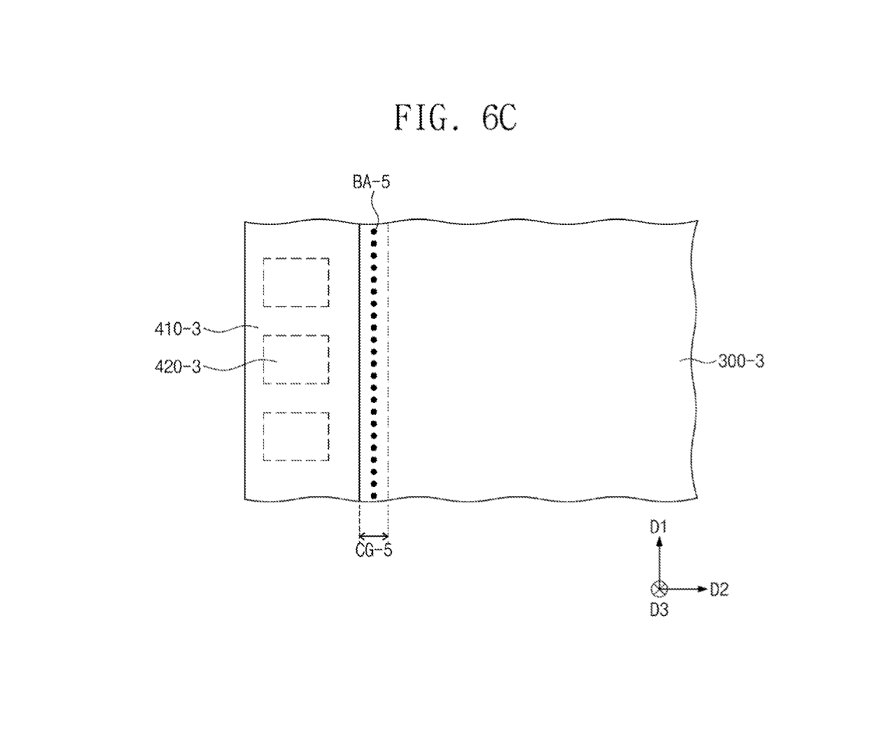

FIGS. 6A to 6C illustrate shapes of bonding regions according to some embodiments of the inventive concept. For concise description, an element previously described with reference to FIGS. 4A to 5B may be identified by a similar or identical reference number without repeating a description thereof.

As shown in FIGS. 6A to 6C, according to some embodiments, a bonding region according to some embodiments of the inventive concept has various shapes. FIG. 6A to 6C show the back surface of the light guide plate 300-3 and the conductive substrate 410B, where the illuminated the light source 420-3 is shown by a dashed line. For example, as shown in FIG. 6A, a plurality of bonding regions BA-3 are provided. The plurality of bonding regions BA-3 extend in the first direction D1 on a contact surface CG-3 and are spaced apart from each other in the second direction D2. Each of the bonding regions BA-3 has a line shape in a plan view. Although FIG. 6A illustrates an example in which there are two line-shaped bonding regions BA-3, embodiments of the inventive concept are not limited thereto. For example, there may be more or fewer line-shaped bonding regions in other embodiments.

In some embodiments, as shown in FIG. 6B, a bonding region BA-4 has a zigzag shape that extends in the first direction D1.

In some embodiments, as shown in FIG. 6C, a bonding region BA-5 includes a plurality of dot patterns arranged in the first direction 1. For example, the bonding region BA-5 includes a plurality of dot patterns that are spaced apart from each other by a predetermined distance in the first direction D1, but embodiments of the inventive concept are not limited thereto.

According to some embodiments, an intensity and irradiation time of a laser beam LS as shown in FIG. 8D in a subsequent bonding process can be adjusted to create the shapes of the bonding regions BA-3, BA-4, and BA-5 shown in FIGS. 6A to 6C. However, embodiments of the inventive concept are not limited to the afore-described bonding region shapes.

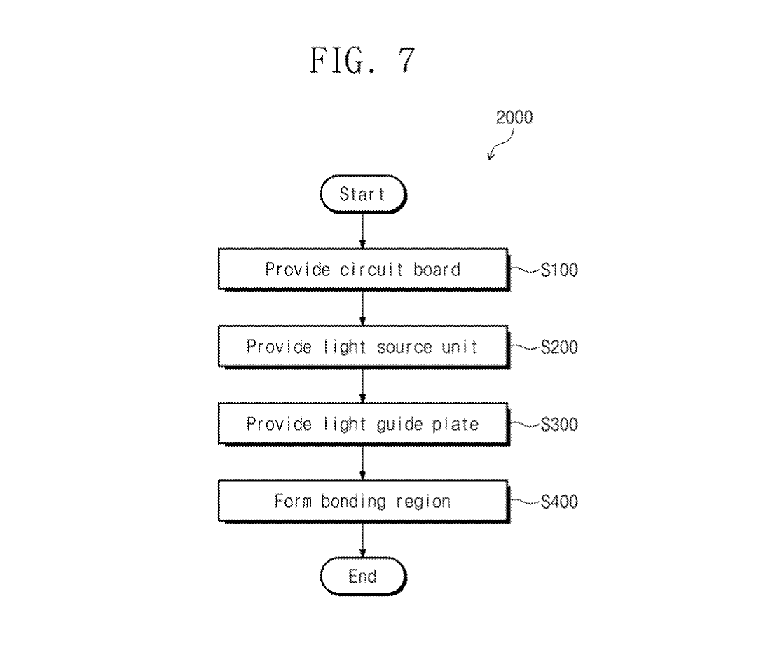

FIG. 7 is a flow chart of a method of fabricating a backlight assembly according to some embodiments of the inventive concept. FIGS. 8A to 8F illustrate a method of fabricating a backlight assembly according to some embodiments of the inventive concept. A method of fabricating a backlight assembly will be described in more detail with reference to FIGS. 7 and 8A to 8F. For concise description, an element previously described with reference to FIGS. 1 to 3 may be identified by a similar or identical reference number without repeating a description thereof.

As shown in. FIG. 7, according to some embodiments, a method 2000 of fabricating a backlight assembly includes providing a circuit board (S100), providing a light source unit (S200), providing a light guide plate (S300), and forming a bonding region between the circuit board and the light guide plate (S400).

Referring to FIGS. 7 and 8A, according to some embodiments, providing the circuit board 410 (S100) includes sequentially depositing the insulating layer 410I and a circuit layer 410C on the conductive substrate 410B. The insulating layer 410I and the circuit layer 410C are deposited to expose a portion of the conductive substrate 410B. The insulating layer 410I electrically separates the conductive substrate 410B from the circuit layer 410C.

Referring to FIGS. 7 and 8B, according to some embodiments, providing the light source unit (S200) includes mounting the light source 420 of the light source unit 400 on a surface of the circuit layer 410C. The light source 420 mounted on the circuit layer 410C is electrically connected to the circuit layer 4100. Electrodes of the light source 420 are connected to the circuit layer 410C.

According to some embodiments, the light source 420 includes the light emitting diode 420L and the body portion 420D. The light emitting diode 420L is mounted on an inner surface of the body portion 420D. The light source 420 is disposed on the circuit layer 410C. The light emitting diode 420L emits light in response to an electrical signal received from the circuit layer 410C. The mounting surface PS is that portion of the circuit layer 410C on which the light source 420 is mounted. The light source 420 includes the light emitting surface EM through which light generated by the light emitting diode 420L is emitted.

According to some embodiments, a reflection layer that exposes the light source 420 and reflects light is deposited on the circuit layer 410C. The conductive substrate 410B effectively radiates heat generated in the light source 420 to the outside, and is formed of or includes a thermally conductive material. For example, the conductive substrate 410B can be formed of or include at least one of a metal or a metal oxide.

According to some embodiments, the insulating layer 410I electrically separates the conductive substrate 410B from the circuit layer 410C. The insulating layer 410I is formed by depositing an electrically insulating and thermally conductive material.

Referring to FIGS. 7 and 8C, according to some embodiments, providing the light guide plate (S300) includes disposing the light guide plate 300 on the conductive substrate 410B to form an interface therebetween. The interface between the light guide plate 300 and the conductive substrate 410B is the contact surface CG. In a present embodiment, the light guide plate 300 is disposed on the conductive substrate 410B so that the contact surface CG is parallel to the mounting surface PS and perpendicular to the light emitting surface EM.

Referring to FIGS. 8D and 8F, according to some embodiments, forming the bonding region (S400) includes irradiating the laser beam LS onto at least a portion of the contact surface CG. The laser beam LS is irradiated onto a portion of the light guide plate 300 that overlaps the contact surface CG in a plan view. The laser beam LS propagates in the third direction D3 through the light guide plate 300 to be incident into the contact surface CG of the conductive substrate 410B. For example, a focus FC of the laser beam LS is located in the conductive substrate 410B.

8E and 8F show the back surface of the light guide plate 300 and the conductive substrate 410B, where the illuminated the light source 420 is shown by a dashed line. Referring to FIGS. 8E and SF, according to some embodiments, the bonding region BA is formed along an imaginary line CX defined within the contact surface CG that extends in the first direction D1. For example, the laser beam LS is irradiated along the imaginary line CX to melt at least a portion of the contact surface CG. The melted portion of the contact surface CG constitutes the bonding region BA. That is, the imaginary line CX defines an irradiation path of the laser beam LS.

According to some embodiments, a glass from the light guide plate 300 and a metal from the conductive substrate 410B are melted by the laser beam LS and then cooled to form a solidified portion, i.e., the bonding region BA. Thus, the bonding region BA is formed of a mixture of glass and metal. In other words, the bonding region BA is formed from different materials from the light guide plate 300 and the circuit board 410 and has a relatively non-uniform surface profile as compared with other regions of the contact surface CG. In some embodiments, a plurality of the bonding regions BA are formed on the contact surface CG.

According to some embodiments, the laser beam LS is an ultra-short pulsed laser beam. For example, the laser beam LS may be a pico-second laser beam or a femto-second laser beam. When the laser beam LS is an ultra-short pulsed laser beam, it is possible to precisely control the bonding process S400.

According to some embodiments, a first distance T1 from the light incidence surface CS-1 to the bonding region BA is less than a second distance T2 from the light incidence surface CS-1 to an incidence position of the rear surface of the light guide plate 300-1, which is located on a propagation path of an edge light, depicted by the arrow of FIG. 8D. Here, edge light refers to a fraction of light that is incident into the light guide plate 300-1 at the largest incident angle relative to the rear surface of the light guide plate 300-1.

In a present embodiment, since the light incidence surface CS-1 is closer to the bonding region BA than to the incidence position, it is possible to prevent light emitted from the light source 420 from being totally reflected by the bonding region BA, which has a non-uniform surface profile, and to prevent the consequent optical loss.

Furthermore, in a present embodiment, portions of the light guide plate 300 and the circuit board 410 are melted by the laser beam LS and then solidified to form the bonding region BA. This increases a bonding strength between the light guide plate 300 and the circuit board 410 and thereby improves the reliability of the display device 1000.

According to some embodiments of the inventive concept, a backlight assembly can prevent light emitted from a light source from being totally reflected by a bonding region, which can reduce an optical loss of the backlight assembly. Furthermore, by performing a bonding process using a laser beam, an adhesion strength of a bonding region is increased to provide a display device in which a light guide plate and a light source unit are more precisely aligned to each other.

While exemplary embodiments of the inventive concept have been particularly shown and described, it will be understood by one of ordinary skill in the art that variations in form and detail may be made therein without departing from the spirit and scope of the attached claims.

What is claimed is:

1. A backlight assembly, comprising:
a light guide plate that includes an incidence surface; and
a light source unit that emits light through a light emitting surface toward the incidence surface;
wherein the light source unit comprises a light source and a circuit board that are electrically connected to each other,
the light source is disposed on the circuit board,
the circuit board extends in a first direction,
at least a portion of the light guide plate contacts the circuit hoard at a contact surface that extends along the first direction, and
a bonding region is disposed on the contact surface.

2. The backlight assembly of claim 1, wherein the contact surface is a portion of a rear surface of the light guide plate that is perpendicular to the incidence surface, and
a width of the contact surface in a second direction that crosses the first direction ranges from 10 μm to 100 μm.

3. The backlight assembly of claim 1, wherein the light guide plate is formed of glass.

4. The backlight assembly of claim 3, wherein the circuit board comprises a base substrate and a circuit layer on the base substrate, and
the base substrate is formed of a conductive material.

5. The backlight assembly of claim 4, wherein the bonding region is formed of a mixed material comprising a material from the circuit board and a material from the light guide plate.

6. The backlight assembly of claim 4, wherein the light source comprises a plurality of light-emitting diodes mounted on the circuit layer that are arranged in the first direction.

7. The backlight assembly of claim 1, wherein the bonding region extends in the first direction and has one of a stripe shape that includes one or more lines, a zigzag shape, or a dotted-line shape.

8. The backlight assembly of claim 1, wherein the contact surface is a portion of an incidence surface of the light guide plate.

9. A display device, comprising:
a light guide plate that includes an incidence surface; and
a light source unit that emits light to the incidence surface,
wherein the light source unit comprises a light source and a circuit board that are electrically connected to each other, the light source is mounted on the circuit board,
at least a portion of the light guide plate is in contact with the circuit board; and
a bonding region is formed where the portion of the light guide plate contacts the circuit board, wherein
the bonding region is formed of a mixed material comprising a material from the circuit board and a material from the light guide plate.

10. The display device of claim 9, wherein the light guide plate is formed of glass.

11. The display device of claim 9, wherein the circuit board comprises a base substrate and a circuit layer disposed on the base substrate, and
the base substrate is formed of a conductive material.

12. The display device of claim 9, wherein the bonding region is a portion of a rear surface of the light guide plate that is perpendicular to the incidence surface.

13. The display device of claim 9, wherein the bonding region is a portion of the incidence surface.

14. The display device of claim 9, further comprising a display panel disposed on the backlight assembly that receives light from the backlight assembly, wherein the display panel comprises a first substrate, a second substrate that faces the first substrate, and a liquid crystal layer interposed between the first and second substrates.

15. The display device of claim 9, further comprising at least one optical sheet disposed on the light guide plate, and a reflection sheet disposed below the light guide plate.

16. A method of fabricating a backlight assembly, comprising:
providing a circuit board;
providing a light source unit on the circuit board;
providing a light guide plate on the circuit board adjacent to the light source unit; and
forming a bonding region between the light guide plate and the circuit board using a laser beam.

17. The method of claim 16, wherein forming a bonding region comprises
irradiating the laser beam vertically through the light guide plate and into at least a portion of the circuit board,
wherein the bonding region is formed along an imaginary line where the circuit board and the light guide plate arc in direct contact with each other.

18. The method of claim 16, wherein providing the circuit board comprises
sequentially depositing an insulating layer and a circuit layer on a conductive substrate,
wherein the insulating layer and the circuit layer expose a portion of the conductive substrate, and the insulating layer electrically separates the conductive substrate from the circuit layer.

19. The method of claim 16, wherein the laser beam is a femto-second laser beam.

20. The method of claim 19, wherein the bonding region is formed by melting at least a portion of the light guide plate and at least a portion of the circuit hoard using the laser beam.
